(19) United States
(12) Patent Application Publication
(10) Pub. No.: US 2016/0240494 A1
(43) Pub. Date: Aug. 18, 2016

(54) RF PACKAGE AND MANUFACTURING METHOD THEREOF

(71) Applicant: Electronics and Telecommunications Research Institute, Daejeon (KR)

(72) Inventor: Myunghoi KIM, Daejeon (KR)

(21) Appl. No.: 15/045,816

(22) Filed: Feb. 17, 2016

(30) Foreign Application Priority Data
Feb. 17, 2015 (KR) 10-2015-0024174

(51) Int. Cl. H01L 23/66; H01L 21/50; H01L 23/498; H01L 23/00

(52) U.S. Cl. CPC H01L 23/66; H01L 24/45; H01L 24/43; H01L 21/50; H01L 23/49838

(57) ABSTRACT

Disclosed is a method of improving performance and increasing a freedom degree of design of an interconnect structure in a radio frequency (RF) package. The RF package may include a package base, a semiconductor die mounted on the package base, a package substrate formed on the package base, the package substrate comprising at least one defected substrate structure (DSS), and a conducting pattern formed on one side of the package substrate and electrically connected with the semiconductor die, wherein the at least one DSS overlaps at least a portion of the conducting pattern in perspective of a top view of the RF package.

### CROSS-REFERENCE TO RELATED APPLICATION

This application claims the priority benefit of Korean Patent Application No. 10-2015-0024174, filed on Feb. 17, 2015, in the Korean Intellectual Property Office, the disclosure of which is incorporated herein by reference.

### BACKGROUND

1. Field of the Invention

Embodiments relate to a radio frequency (RF) package and a manufacturing method thereof including a method of improving performance and increasing a freedom degree of design of an interconnect structure in the RF package, and more particularly, to the RF package and the manufacturing method thereof to enhance an infrared (IR) drop feature and mechanical stability while maintaining impedance matching.

2. Description of the Related Art

A semiconductor wafer may include hundreds or thousands of chips in which an identical electric circuit is printed. Each of the chips may not independently communicate with an outside. Therefore, a semiconductor packaging process may connect electrical wirings to each of the chips to be connectable with the outside, and seal and package the chips to make them more resistant to external damage, for example, physical damage and chemical damage. Concisely, the semiconductor packaging process corresponding to a die packaging process may be a final process among processes for manufacturing a semiconductor apparatus.

A radio frequency (RF) semiconductor may be used in various fields such as a communication field and a military field, and used in environments varying in electrical and mechanical aspects. Accordingly, the semiconductor packaging process may be important to protect the RF semiconductor in various environments. Although semiconductor packaging technology develops according to progress in semiconductor technology, a semiconductor package may be a reason for performance deterioration in a modern electronic device that pursues performance improvement and miniaturization of a module. In particular, performance deterioration in a semiconductor designing and manufacturing stage may be noticeable in a semiconductor using a high frequency or a high output RF semiconductor. To improve the performance of the semiconductor, impedance matching and a low infrared (IR) drop feature may be considered. However, the impedance matching, the low IR drop feature, package feasibility with respect to economy, mechanical stability, and the like may be found to be contradictory when the interconnect structure is designed and manufactured. Thus, the RF package manufacturing method to improve the IR drop feature and the mechanical stability is required, while the impedance matching is maintained.

### SUMMARY

According to an aspect, there is provided a radio frequency (RF) package including a package base, a semiconductor die mounted on the package base, a package substrate formed on the package base, the package substrate including at least one defected substrate structure (DSS), and a conducting pattern formed on one side of the package substrate and electrically connected with the semiconductor die.

The at least one DSS may overlap at least a portion of the conducting pattern in perspective of a top view of the RF package. In an example, the at least one DSS may be separate from the conducting pattern of the package substrate. In another example, at least a portion of the at least one DSS may be in contact with the package base.

The RF package may further include an interconnect structure configured to electrically connect the semiconductor die and the conducting pattern. The interconnect structure may be a bonding wire. The RF package may further include a connection pin formed on the conducting pattern, the connection pin electrically connected with the conducting pattern.

In an example, the at least one DSS may have a shape of a rectangular parallelepiped. In another example, the at least one DSS may have a shape of a regular hexahedron. In still another example, the at least one DSS may have a shape of at least a portion of a cylinder.

According to another aspect, there is provided a package substrate used for a radio frequency (RF) package including at least one defected substrate structure (DSS), wherein the package substrate is combined with one surface of a package base and one surface of a conducting pattern, and the package substrate surrounds a semiconductor die mounted on the one surface of the package base.

The at least one DSS may overlap at least a portion of the conducting pattern in perspective of a top view of the RF package. In an example, the at least one DSS may be to be separate from the one surface of the conducting pattern. In another example, at least a portion of the at least one DSS may be in contact with the one surface of the package base.

In an example, the at least one DSS may have a shape of a rectangular parallelepiped. In another example, the at least one DSS may have a shape of a regular hexahedron. In still another example, the at least one DSS may have a shape of at least a portion of a cylinder.

According to still another aspect, there is provided a radio frequency (RF) package manufacturing method including forming a package base, mounting a semiconductor die on the package base, forming a package substrate including at least one defected substrate structure (DSS) on the package base, forming a conducting pattern in one surface of the package substrate, and electrically connecting the semiconductor die and the conducting pattern.

The at least one DSS may be formed to overlap at least a portion of the conducting pattern in perspective of a top view of the RF package. In an example, the at least one DSS may be formed to be separate from the conducting pattern. In still another example, the at least a portion of the at least one DSS may be in contact with the package base.

The electrically connecting of the semiconductor die and the conducting pattern may include forming an interconnect structure configured to electrically connect the semiconductor die and the conducting pattern. The method may further include forming a connection pin on the conducting pattern, the connection pin electrically connected with the conducting pattern.

In an example, the at least one DSS may have a shape of a rectangular parallelepiped. In another example, the at least one DSS may have a shape of a regular hexahedron. In still another example, the at least one DSS may have a shape of at least a portion of a cylinder.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a cross-sectional view of a radio frequency (RF) package including a defected substrate structure (DSS) according to an example embodiment;

FIG. 2 is a top view of an RF package including a defected substrate structure (DSS) according to an example embodiment;

FIG. 3 is a top view of an RF package including a defected substrate structure (DSS) according to an example embodiment; and

FIG. 4 is a top view of an RF package including a defected substrate structure (DSS) according to an example embodiment.

### DETAILED DESCRIPTION

Hereinafter, some example embodiments will be described in detail with reference to the accompanying drawings. Regarding the reference numerals assigned to the elements in the drawings, it should be noted that the same elements will be designated by the same reference numerals, wherever possible, even though they are shown in different drawings. Also, in the description of embodiments, detailed description of well-known related structures or functions will be omitted when it is deemed that such description will cause ambiguous interpretation of the present disclosure.

It should be understood, however, that there is no intent to limit this disclosure to the particular example embodiments disclosed. On the contrary, example embodiments are to cover all modifications, equivalents, and alternatives falling within the scope of the example embodiments. Like numbers refer to like elements throughout the description of the figures.

In addition, terms such as first, second, A, B, (a), (b), and the like may be used herein to describe components. Each of these terminologies is not used to define an essence, order or sequence of a corresponding component but used merely to distinguish the corresponding component from other component(s). It should be noted that if it is described in the specification that one component is “connected”, “coupled”, or “joined” to another component, a third component may be “connected”, “coupled”, and “joined” between the first and second components, although the first component may be directly connected, coupled or joined to the second component.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Various example embodiments will now be described more fully with reference to the accompanying drawings in which some example embodiments are shown. In the drawings, the thicknesses of layers and regions are exaggerated for clarity.

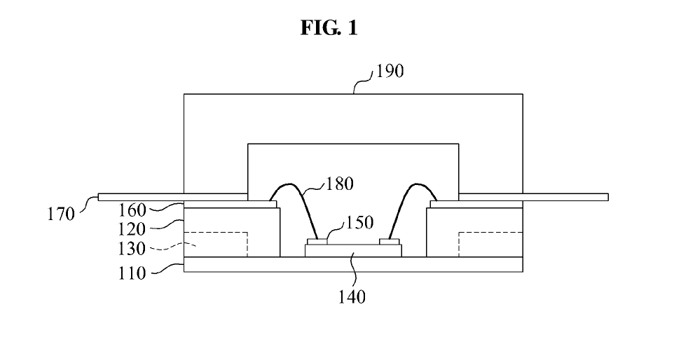

FIG. 1 is a cross-sectional view of a radio frequency (RF) package including a defected substrate structure (DSS) according to an example embodiment. FIG. 1 illustrates an example of a related RF package to which the DSS according to an example embodiment is applied.

Referring to FIG. 1, the RF package includes a package base 110, a package substrate 120, a DSS 130, a semiconductor die 140, a bond pad 150, a conducting pattern 160, a connection pin 170, a bonding wire 180, and a package lid 190.

In general, the RF package includes a first level interconnect electrically connecting a semiconductor die and a package, and a second level interconnect electrically connecting the package and an outside of the package. As illustrated in FIG. 1, the bonding wire 180 connecting the bond pad 150 on the semiconductor die 140 and the conducting pattern 160 on the package substrate 120 corresponds to the first level interconnect. The connection pin 170 connectable with the conduction pattern 160 on the package substrate 160 and an outside of the package corresponds to the second level interconnect.

To reduce performance degradation of an RF signal in the first level interconnect, a connection length of an interconnect structure may be minimized For example, when the bonding wire 180 is used as illustrated in FIG. 1, the performance degradation in the first level interconnect may be reduced when a length of the bonding wire 180 is relatively short. Accordingly, a height of the package substrate 120 may be decreased such that a distance between the bond pad 150 on the semiconductor die 140 and the conducting pattern 160 on the package substrate 120 may be decreased. Further, the height of the package substrate 120 may be identical to a thickness of the semiconductor die 140 such that heights of the bond pad 150 on the semiconductor die 140 and the conducting pattern 160 on the package substrate 120 may be identical.

However, it is difficult to form the package substrate 120 having a low height since the thickness, for example, approximately 100 micrometer generally, of the semiconductor die 140 is relatively thin. Also, the conducting pattern 160 may have a relatively narrow width in order to maintain impedance matching on the package substrate 120 having a low height. However, the narrow width of the conducting pattern 160 may cause an increase of an infrared (IR) drop. In addition, the narrow width of the conducting pattern 160 may cause a decrease in an adhesion area to which the connection pin 170 adheres, thereby reducing mechanical stability.

As described above, an IR drop feature and the mechanical stability may have opposite effect on improvement in RF signal performance in the first level interconnect. According to an example embodiment, a DSS may be applied to an RF package such that the mechanical stability may be improved and the performance degradation of the RF signal may be reduced while the impedance matching is maintained.

As illustrated in FIG. 1, the package substrate 120 includes the DSS 130. The DSS 130 may be an opening or a groove formed in the package substrate 120. A feature impedance of a signal line existing on a dielectric material may have a feature in inverse proportion to a permittivity. Thus, in a case of the signal line providing an identical feature impedance, a width of the signal line may be designed to be relatively great according to the permittivity being relatively low.

As illustrated in FIG. 1, when the DSS 130 is formed in the package substrate 120 under the conducting pattern 160, an effective permittivity of the conducting pattern 160 may be decreased. Thus, the effective permittivity of the conducting pattern 160 may be decreased through the formation of the DSS 130 such that the conducting pattern 160 having a wider width may be usable compared to when the DSS 130 is absent while providing an identical impedance. Since the impedance matching is maintained on the package substrate 130 having a relatively low height, the performance degradation of the RF signal in the first level interconnect may be prevented. When the conducting pattern 160 having a relatively low height is used, the IR drop may be decreased and a power loss may be reduced. In addition, the conducting pattern 160 having a relatively wide width may increase the adhesion area to which the connection pin 170 adheres, thereby improving the mechanical stability.

The DSS 130 may be formed to have various positions, forms, and numbers according to requirements on performance or process.

In an example, the DSS 130 may be formed to overlap at least a portion of the conducting pattern 160 in perspective of a top view of the DSS 130. The DSS 130 is to be separate from a surface on which the conducting pattern 160 is in contact with the package substrate 130 for the mechanical stability. For example, the DSS 130 may be formed in a lower portion of the package substrate 130 to be in contact with the package base 110. The DSS may be formed to be in contact with an outside surface of the package substrate 130 and is to be separate from an inner surface of the package substrate 130. A position of the DSS 130 is not limited to the descriptions in the present disclosure, and the position of the DSS 130 may be freely selected according to requirements on performance or process.

In an example, the DSS 130 may have a shape of a rectangular parallelepiped. In another example, the DSS 130 may have a shape of a regular hexahedron. In still another example, the DSS 130 may have a shape of a cylinder or a shape of at least a portion of a cylinder. A shape of the DSS 130 is not limited to the descriptions in the present disclosure, and the shape of the DSS 130 may be freely selected according to requirements on performance or process.

In an example, the DSS 130 may include a single opening or a groove. In another example, the DSS 130 may include a plurality of openings or grooves. For example, the DSS 130 may include openings or grooves of a number identical to a number of the connection pins 170. Concisely, the DSS 130 may include an opening or a groove corresponding to each connection pin 170. Alternatively, the DSS 130 may include openings or grooves of a number different from the number of the connection pins 170. The DSS 130 may include an opening or a groove corresponding to a plurality of connection pins 170, or the DSS 130 may include a plurality of openings or grooves corresponding to a single connection pin 170. A number of the DSS 130 is not limited by the descriptions in the present disclosure, and the number of the DSS 130 may be freely selected according to requirements on performance or process.

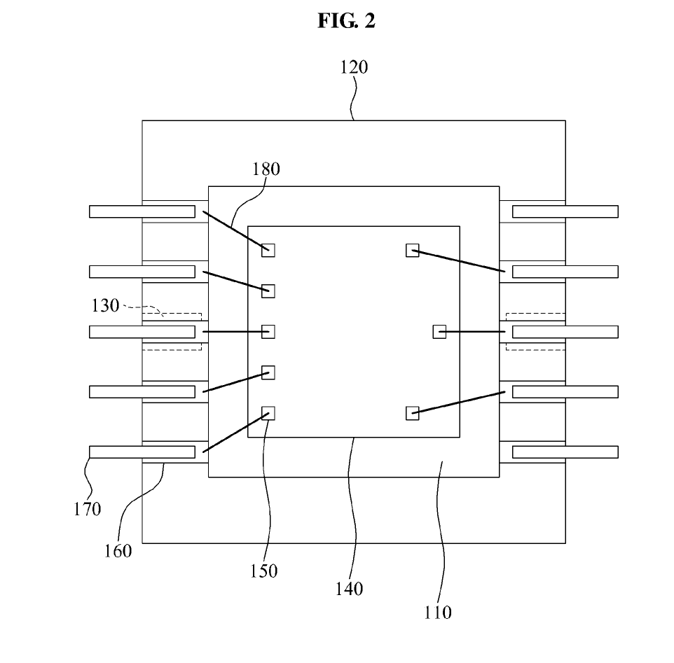

FIG. 2 is a top view of an RF package including a defected substrate structure (DSS) according to an example embodiment. The RF package illustrated in FIG. 2 is only an example for description, a part of the configuration may be omitted or exaggerated.

As illustrated in FIG. 2, the RF package includes the DSS 130 formed in the package substrate 120 and under the conducting pattern 160. For example, the DSS 130 may have a cross section shape of a square, a rectangle, or a circle in perspective of a side view of the RF package.

As illustrated in FIG. 2, the DSS 130 may be formed to overlap at least a portion of the conducting pattern 160 in perspective of a top view of the RF package. Based on the aforementioned arrangement, the DSS 130 may decrease the effective permittivity of the conducting pattern 160 on the package substrate 120. As described above, the effective permittivity of the conducting pattern 160 through the formation of the DSS 130 such that the conducting pattern 160 having a wider width may be usable as compared to when the DSS 130 is absent while providing the identical impedance. Since the impedance matching is maintained on the package substrate 120 having a relatively low height, the performance degradation of the RF signal in the first level interconnect may be prevented and the relatively low IR drop feature and improved mechanical stability may be obtained.

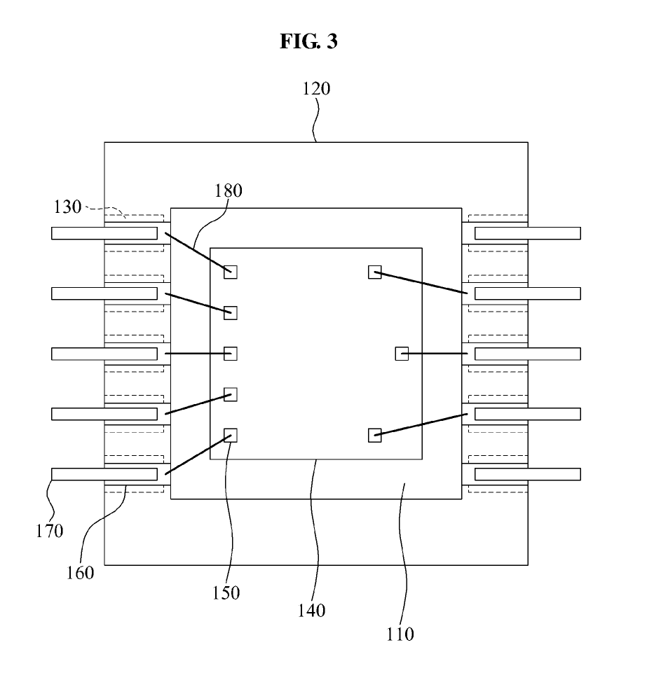

FIG. 3 is a top view of an RF package including a defected substrate structure (DSS) according to an example embodiment. The RF package illustrated in FIG. 3 is only an example for description, a part of the configuration may be omitted or exaggerated.

As illustrated in FIG. 3, the RF package includes the DSS 130 formed in the package substrate 120 and under the conducting pattern 160. As illustrated in FIG. 3, the DSS 130 includes openings or grooves corresponding to each connection pin 170. As illustrated in FIG. 3, the DSS 130 may be formed to overlap at least a portion of the conducting pattern 160 in perspective of a top view of the RF package. By including the DSS 130, an effect that may be achieved similarly to the examples described with reference to FIGS. 1 and 2 may also be achieved.

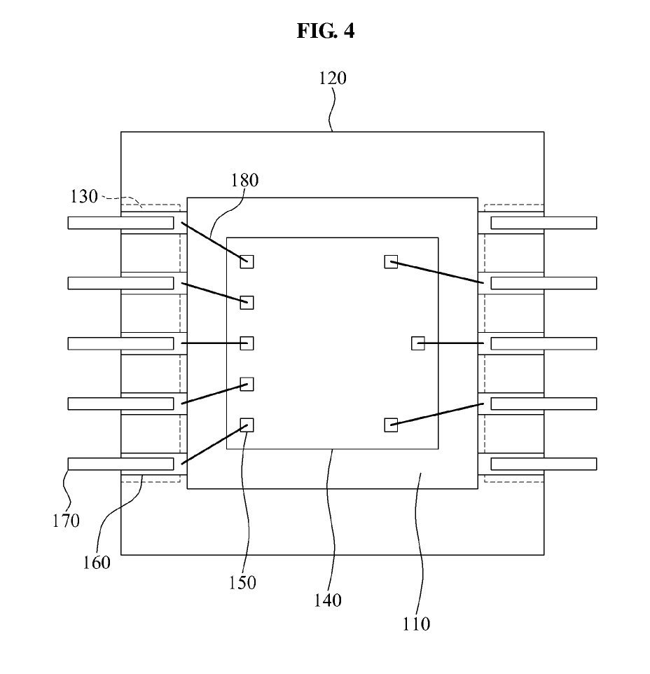

FIG. 4 is a top view of an RF package including a defected substrate structure (DSS) according to an example embodiment. The RF package illustrated in FIG. 4 is only an example for description, a part of the configuration may be omitted or exaggerated.

As illustrated in FIG. 4, the RF package includes the DSS 130 formed in the package substrate 120 and under the conducting pattern 160. As illustrated in FIG. 4, the DSS 130 includes an opening or a groove corresponding to the plurality of connection pins 170. As illustrated in FIG. 4, the DSS 130 may be formed to overlap at least a portion of the conducting pattern 160 in perspective of a top view of the RF package. By including the DSS 130, an effect that may be achieved similarly to the examples described with reference to FIGS. 1 and 2 may also be achieved.

The above-described embodiments of the present disclosure may be recorded in non-transitory computer-readable media including program instructions to implement various operations embodied by a computer. The media may also include, alone or in combination with the program instructions, data files, data structures, and the like. Examples of non-transitory computer-readable media include magnetic media such as hard disks, floppy disks, and magnetic tapes; optical media such as CD ROMs and DVDs; magneto-optical media such as floptical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described embodiments of the present disclosure, or vice versa.

Although a few embodiments of the present disclosure have been shown and described, the present disclosure is not limited to the described embodiments. Instead, it would be appreciated by those skilled in the art that changes may be made to these embodiments without departing from the principles and spirit of the invention, the scope of which is defined by the claims and their equivalents.

What is claimed is:

1. A radio frequency (RF) package, comprising:
a package base;
a semiconductor die mounted on the package base;
a package substrate formed on the package base, the package substrate comprising at least one defected substrate structure (DSS); and
a conducting pattern formed on one side of the package substrate and electrically connected with the semiconductor die.

2. The RF package of claim 1, wherein the at least one DSS overlaps at least a portion of the conducting pattern in perspective of a top view of the RF package.

3. The RF package of claim 1, wherein the at least one DSS is to be separate from the conducting pattern of the package substrate.

4. The RF package of claim 1, wherein at least a portion of the at least one DSS is in contact with the package base.

5. The RF package of claim 1, further comprising:
an interconnect structure configured to electrically connect the semiconductor die and the conducting pattern.

6. The RF package of claim 5, wherein the interconnect structure is a bonding wire.

7. The RF package of claim 1, further comprising:
a connection pin formed on the conducting pattern, the connection pin electrically connected with the conducting pattern.

8. The RF package of claim 1, wherein the at least one DSS has a shape of a rectangular parallelepiped.

9. The RF package of claim 1, wherein the at least one DSS has a shape of a regular hexahedron.

10. The RF package of claim 1, wherein the at least one DSS has a shape of at least a portion of a cylinder.

11. A package substrate used for a radio frequency (RF) package, the package substrate comprising:
at least one defected substrate structure (DSS), wherein the package substrate is combined with one surface of a package base and one surface of a conducting pattern, and the package substrate surrounds a semiconductor die mounted on the one surface of the package base.

12. The package substrate of claim 11, wherein the at least one DSS overlaps at least a portion of the conducting pattern in perspective of a top view of the RF package.

13. The package substrate of claim 11, wherein the at least one DSS is to be separate from the one surface of the conducting pattern.

14. The package substrate of claim 11, wherein at least a portion of the at least one DSS is in contact with the one surface of the package base.

15. A radio frequency (RF) package manufacturing method, the method comprising:
forming a package base;
mounting a semiconductor die on the package base;
forming a package substrate comprising at least one defected substrate structure (DSS) on the package base;
forming a conducting pattern in one surface of the package substrate; and
electrically connecting the semiconductor die and the conducting pattern.

16. The method of claim 15, wherein the at least one DSS is formed to overlap at least a portion of the conducting pattern in perspective of a top view of the RF package.

17. The method of claim 15, wherein the at least one DSS is formed to be separate from the conducting pattern.

18. The method of claim 15, wherein the at least a portion of the at least one DSS is in contact with the package base.

19. The method of claim 15, wherein the electrically connecting of the semiconductor die and the conducting pattern comprises forming an interconnect structure configured to electrically connect the semiconductor die and the conducting pattern.

20. The method of clam 15, further comprising:
forming a connection pin on the conducting pattern, the connection pin electrically connected with the conducting pattern.
